(19) United States
(12) Patent Application Publication
(10) Pub. No.: US 2016/0351543 A1
(43) Pub. Date: Dec. 1, 2016

(54) PRINTED CIRCUIT BOARD, PACKAGE SUBSTRATE AND PRODUCTION METHOD FOR SAME

(71) Applicant: LG INNOTEK CO., LTD., Seoul (KR)

(72) Inventors: Sung Wuk RYU, Seoul (KR); Dong Sun KIM, Seoul (KR); Ji Haeng LEE, Seoul (KR); Sang Hyuck NAM, Seoul (KR)

(21) Appl. No.: 15/117,345

(22) PCT Filed: Jan. 28, 2015
(86) PCT No.: PCT/KR2015/000906

§ 371 Date: Aug. 8, 2016

(30) Foreign Application Priority Data
Feb. 6, 2014 (KR) 10-2014-0013468

(51) Int. Cl. H01L 25/065; H01L 25/00; H01L 21/48; H01L 23/498; H01L 23/00

(52) U.S. Cl. CPC H01L 25/0657; H01L 23/49816; H01L 23/49838; H01L 24/09; H01L 23/49822; H01L 23/49827; H01L 21/4853; H01L 25/50; H01L 24/81; H01L 21/486; H01L 2224/08238; H01L 2225/06517; H01L 2225/0652; H01L 2225/06548; H01L 2225/06572; H01L 2924/15311; H01L 2924/19105; H01L 2924/19041; H01L 2924/19042; H01L 2924/19043; H01L 2924/15747; H01L 2924/15701; H01L 2924/0105; H01L 2924/15738; H01L 2924/01079; H01L 2224/81192

(57) ABSTRACT

A printed circuit board according to the present invention comprises: an insulating substrate; a plurality of pads formed on the upper surface of the insulating substrate; a protective layer which comprises an opening part for exposing the upper surfaces of the plurality of pads, and is formed on the insulating substrate; and a metal bump which is formed on the first pad and the second pad in the plurality of pads, and projects above the surface of the protective layer, and, here, the first pad is formed to the left of the central upper part of the insulating substrate, while the second pad is formed to the right of the central upper part of the insulating substrate.

### TECHNICAL FIELD

The present invention relates to a package substrate and a production method therefor.

### BACKGROUND ART

In general, a package substrate has a form in which a first substrate having a memory chip attached thereto and a second substrate having a processor chip attached thereto are connected as one.

The package substrate has advantages in that, as the processor chip and the memory chip are manufactured as one package, the mounting area of the chips can be reduced, and a signal can be transmitted at a high speed through a short path.

Due to this advantage, the package substrate is widely used in mobile devices, and the like.

FIG. 1 is a sectional view illustrating a package substrate according to a related art.

Referring to FIG. 1, the package substrate includes a first substrate 20 and a second substrate 20 attached onto the first substrate 20.

The first substrate 20 includes a first insulating layer 1, circuit patterns 4 formed on at least one surface of the first insulating layer 1, a second insulating layer 2 formed on the first insulating layer 2, a third insulating layer 3 formed under the first insulating layer 1, a conductive via 5 formed inside at least one of the first insulating layer 1, the second insulating layer 2, and the third insulating layer 3, a pad 6 formed on an upper surface of the second insulating layer 2, a plurality of bonding paste 7 formed on the pad 6, a memory chip 8 formed on at least one bonding paste 7 among the plurality of bonding pastes 7, a first protective layer 10 exposing a partial upper surface of the pad 6 therethrough, and a second protective layer 9 formed on the first protective layer 10 to cover the memory chip 8.

In addition, the second substrate 30 includes a fourth insulating layer 11, a circuit pattern 12 formed on at least one surface of the fourth insulating layer 11, a pad 13 formed on at least one surface of the fourth insulating layer 11, a conductive via 14 formed inside the fourth insulating layer 11, a processor chip 15 formed on the fourth insulating layer 11, and a connection member S connecting the processor chip 15 to the pad 13.

The package substrate according to the related art shown in FIG. 1 illustrates a schematic view of a package on package (PoP) to which a through mold via (TMV) technology based on a laser technology is applied.

According to the TMV technology, after the first substrate 20 is molded, a conductive via connected to a pad is formed through a laser process, and accordingly, a solder ball (bonding paste) is printed in the conductive via.

In addition, the second substrate 30 is attached onto the first substrate 20 by the printed solder ball.

However, the related art has a limitation in forming a fine pitch because the first substrate is connected to the second substrate using the solder ball.

In addition, according to the related art, since the solder ball 7 is used, issues such as a solder crack, a solder bridge, and a solder collapse may occur.

### DISCLOSURE OF THE INVENTION

### Technical Problem

Embodiments provide a printed circuit board having a novel structure.

Embodiments also provide a printed circuit board in which a fine pitch can be easily formed.

Technical objects to be achieved in the present invention are not limited to the mentioned technical objects, and those skilled in the art may clearly understand another non-mentioned technical object from the description of the present invention below.

### Technical Solution

According to an embodiment of the present invention, there is provided a printed circuit board including: an insulating substrate; a plurality of pads formed on an upper surface of the insulating substrate; a protective layer including an opening an opening part exposing upper surfaces of the plurality of pads, the protective layer being formed on the insulating substrate; and a metal bump formed on the first pad and the second pad among the plurality of pads, the metal bump protruding upward of a surface of the protective layer, wherein the first pad is formed to the left of the central upper part of the insulating substrate, while the second pad is formed to the right of the central upper part of the insulating substrate.

In addition, the printed circuit board includes an electronic device attached onto at least one third pad among the plurality of pads by a bonding ball formed on the third pad, and the electronic device is formed on an upper portion of the insulating substrate to be exposed to the outside.

Further, the metal bump includes a burial bump formed on the first pad and the second pad, to be buried in the opening of the protective part, and a protruding bump formed on the burial bump, to protrude upward of the surface of the protective layer.

In addition, each of the burial bump and the protruding bump has upper and lower widths equal to each other, and the upper and lower widths of the first bump are narrower than those of the second bump.

In addition, an upper surface of the metal bump is higher than that of the electronic device attached to the upper portion of the insulating substrate.

In addition, the protruding bump includes: a first protruding bump formed of the same material as the burial bump; and a second protruding bump formed on the first protruding bump, the second protruding bump being a surface treatment surface for protecting an upper surface of the first protruding bump.

Meanwhile, according to an embodiment of the present invention, there is provided a package substrate including: a lower substrate to which at least one electrode device or first chip is attached; and an upper substrate to which at least one second chip is attached, the upper substrate being coupled to the lower substrate, wherein the lower substrate includes: an insulating substrate; and a plurality of metal bumps protruding upward of a surface of the insulating substrate on the insulating substrate, the plurality of metal bumps having upper surfaces on which a solder ball is formed, and wherein the upper substrate is supported by the metal bumps, to be attached onto the lower substrate through the solder ball.

In addition, the electronic device or first chip of the lower substrate is formed in a region between the plurality of metal bumps at an upper portion of the insulating substrate to be exposed to the outside, and has a lower height than the plurality of metal bumps.

Further, a plurality of pads connected to the plurality of metal bumps and a protective layer having an opening exposing upper surfaces of the plurality of pads are formed on the insulating substrate. The metal bump includes: a burial bump formed on the plurality of pads, to be buried in the opening of the protective layer; and a protruding bump formed on the first bump, to protrude upward of a surface of the protective layer.

In addition, each of the burial bump and the protruding bump has upper and lower widths equal to each other, and the upper and lower widths of the first bump are narrower than those of the second bump.

In addition, the protruding bump includes: a first protruding bump formed of the same material as the burial bump; and a second protruding bump formed on the first protruding bump, the second protruding bump being a surface treatment surface for protecting an upper surface of the first protruding bump.

In addition, the package substrate may further include a molding layer formed between the lower substrate and the upper substrate, the molding layer allowing the electronic device or first chip of the lower substrate, exposed to the outside, and the metal bumps to be buried therein.

Meanwhile, according to an embodiment of the present invention, there is provided a method for producing a package substrate, the method including: manufacturing a lower substrate by preparing an insulating substrate having an upper surface on which a plurality of pads are formed, forming a protective layer having an opening exposing upper surfaces of the plurality of pads therethrough, and forming, on the plurality of pads, a plurality of metal bumps protruding upward of a surface of the protective layer; manufacturing an upper substrate to which at least one chip is attached; forming a bonding ball on the metal bump of the lower substrate; and disposing the upper substrate on the bonding ball, thereby attaching the upper substrate supported by the plurality of metal bumps onto the lower substrate.

In addition, the manufacturing of the lower substrate further includes attaching an electronic device or a first chip onto at least one pad formed in a region between the plurality of metal bumps. The electronic device or first chip is formed at an upper portion of the lower substrate to be exposed to the outside.

Further, the electronic device or first chip has a height lower than that of the plurality of metal bumps.

In addition, the forming of the metal bump includes: forming a mask including a window having a larger width than the opening of the protective layer while exposing the upper surfaces of the plurality of pads on the protective layer and the opening of the protective layer therethrough; forming a first bump buried in the entire region of the opening; and forming a second bump buried in the window of the mask on the first bump.

In addition, the method may further include forming a molding layer in a region between the lower substrate and the upper substrate, thereby allowing the plurality of metal bumps and the electronic device or first chip to be buried in the molding layer.

### Advantageous Effects

According to the embodiments of the present invention, a metal post is formed on the lower substrate, and the upper substrate is attached onto the lower substrate using the metal post, thereby producing the package substrate, so that a fine pith can be formed. Accordingly, the productivity of a manufacturer can be maximized.

In addition, according to the embodiments of the present invention, the electronic device exposed to the outside is attached on the lower substrate, and the attachment space of the electronic device is molded using resin in the package process performed together with the upper substrate. Accordingly, the degree of freedom can be enhanced in the design of the substrate for the attachment of the electronic device, and the productivity can be improved in terms of product yield.

In addition, according to the embodiments of the present invention, since a molding region formed between the lower substrate and the upper substrate is supported by the metal post formed on the lower substrate, the electronic device buried in the molding region can be efficiently protected, so that the reliability of the package substrate can be improved.

### BRIEF DESCRIPTION OF THE DRAWINGS

FIG. 1 is a sectional view illustrating a package substrate according to a related art.

FIG. 2 is a view illustrating a printed circuit board according to an embodiment of the present invention.

FIGS. 3 to 14 are sectional views illustrating a method for manufacturing the printed circuit board shown in FIG. 2 in sequence of processes.

FIG. 15 is a sectional view illustrating a package substrate according to an embodiment of the present invention.

FIGS. 16 to 18 are sectional views illustrating a production method for the package substrate shown in FIG. 15 in sequence of processes.

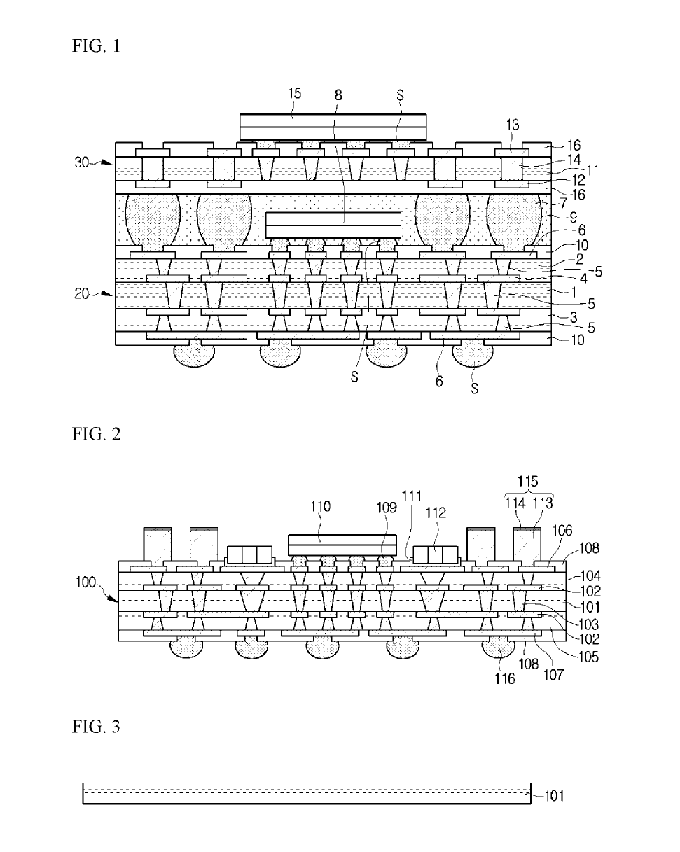

### BEST MODE FOR CARRYING OUT THE INVENTION

Hereinafter, embodiments of the present invention will be described in detail with reference to accompanying drawings so that those skilled in the art can easily work with the embodiments. However, the present invention can be implemented in various manners, and thus should not be construed to be limited to the embodiments disclosed herein.

In the following description, when a predetermined part “includes” a predetermined component, the predetermined part does not exclude other components, but may further include other components unless indicated otherwise.

The thickness and size of each layer shown in the drawings may be exaggerated, omitted or schematically drawn for the purpose of convenience or clarity. In addition, the size of elements does not utterly reflect an actual size. The same reference numbers will be assigned the same elements throughout the drawings.

In the description of the embodiments, it will be understood that, when a layer (or film), a region, or a plate is referred to as being “on” another part, it can be “directly” or “indirectly” over the other part, or one or more intervening layers may also be present. On the contrary, it will be understood that, when a certain part is referred to as being “directly on” another part, one or more intervening layers may be absent.

FIG. 2 is a view illustrating a printed circuit board according to an embodiment of the present invention.

Referring to FIG. 2, the printed circuit board 100 according to the embodiment includes a first insulating layer 101, a circuit pattern 102, a conductive via 103, a second insulating layer 104, a third insulating layer 105, a first pad 106, a second pad 107, a protective layer 108, a first solder ball 109, a processor chip 110, an electronic device 112, a bonding paste 111, a second solder ball 116, and a metal bump 115.

The first insulating layer 101 may be a core substrate.

Although the first insulating layer 101 may be a support substrate of the printed circuit board having a single circuit pattern formed thereon, the first insulating layer 101 may refer to a region in which any one circuit pattern is formed in a substrate having a plurality of lamination structures.

The second insulating layer 104 is formed on the first insulating layer 101, and the third insulating layer 105 is formed under the first insulating layer 101.

The first the third insulating layers 101, 104, and 105 form an insulating plate, and may be a thermosetting or thermoplastic polymeric substrate, a ceramic substrate, an organic-inorganic composite material substrate, or a glass fiber impregnated substrate. When the insulating layers include polymeric resin, the insulating layers may include epoxy-based insulating resin, such as FR-4, bismaleimide triazine (BT), or ajinomoto build up film (ABF). Alternatively, the insulating layers may include polyimide-based resin, but the present invention is not particularly limited thereto.

The first to third insulating layers 101, 104, and 105 may be formed of different materials. For example, the first insulating layer 101 may be a glass fiber impregnated substrate, and the second and third insulating layers 104 and 105 may include an insulating sheet formed of only resin.

The first insulating layer 101 is a center insulating layer, and may be formed thicker than the second and third insulating layers 104 and 105.

The circuit pattern 102 is formed on at least one of upper and lower surfaces of the first insulating layers 101.

The circuit pattern 102 may be formed through typical processes of manufacturing the printed circuit board, such as an additive process, a subtractive process, a modified semi-additive process (MSAP), and a semi-additive process (SAP), and detailed descriptions thereof will be omitted.

In addition, the conductive via 103 is formed inside the first insulating layer 101 to connect, to each other, circuit patterns formed in different layers from each other.

External circuit patterns (not shown) are also formed on both of the second insulating layer 104 formed on the first insulating layer 101 and the third insulating layer 105 formed under the first insulating layer 101.

The external circuit patterns (not shown) are also formed on exposed surfaces of the second insulating layer 104 formed on the first insulating layer 101 and the third insulating layer 105 formed under the first insulating layer 101.

The external circuit patterns may be the pads 106 and 107 shown in this figure. That is, the external circuit patterns are formed through the same process as the pads 106 and 107, and are classified into a pattern and a pad according to functions thereof.

In other words, circuit patterns are formed on the surfaces of the second insulating layer 104 and the third insulating layer 105. According to the functions of the circuit patterns, some of the circuit patterns may be external circuit patterns and the other circuit patterns may be the pads 106 and 107 connected to a chip or another substrate.

In addition, conductive vias are also formed inside the second and third insulating layers 104 and 105.

The conductive via 103 may be formed by forming, through a laser process, a via hole through which at least one of the first, second, and third insulating layers 101, 104, and 105 are opened, and filling metallic paste in the formed via hole.

In this case, the metallic material constituting the conductive via 103 may be any one material selected from the group consisting of Cu, Ag, Sn, Au, Ni and Pd. The filling of the metallic material may be performed through any one of electroless plating, electrolytic plating, screen printing, sputtering, evaporation, inkjetting, and dispensing, or a combination thereof.

Meanwhile, the via hole may be formed through any one of a machining process, a laser process, and a chemical process.

A milling process, a drill process, and a routing process may be used when the via hole is formed through the machining process, a UV laser scheme or a Co2 laser scheme may be used when the via hole is formed through the laser process, and chemicals including aminosilane or ketones may be used when the via hole is formed through the chemical process, thereby opening the first, second, and third insulating layers 101, 104, and 105.

Meanwhile, the laser process is a cutting scheme that concentrates optical energy onto a surface to melt and evaporate a portion of a material so that the material is formed in a desired shape. According to the laser process, even a complex shape can be easily processed in a computer program, and a composite material, which may be not cut through another scheme, can be processed.

In addition, the laser process enables a cutting diameter to be 0.005 mm or more, and has a wide processing thickness range.

Preferably, a YAG (Yttrium Aluminum Garnet) laser, a CO2 laser, or an ultraviolet laser may be used for a laser process drill. The YAG laser is a laser capable of processing both of a copper layer and an insulating layer, and the CO2 laser is a laser capable of processing only the insulating layer.

The protective layer 108 is formed on the surfaces (surfaces exposed to the outside or surfaces having the pad formed thereon) of the second and third insulating layers 104 and 105.

The protective layer 108 has an opening to expose an upper surface of the first pad 106.

That is, the protective layer 108 is used to protect the surfaces of the second and third insulating layers 104 and 105. The protective layer 108 is formed throughout the entire surfaces of the second and third insulating layers 104 and 105. The protective layer 108 has an opening to open an upper surface of a lamination structure of the first pad 106.

The protective layer 108 may include at least one layer formed using at least one of solder resist (SR), oxide, and Au.

The first pads 106 exposed through the openings of the protective layer 108 are classified into various pads according to functions thereof.

That is, the first pads 106 are classified into a pad connected to the processor chip 110 or the electronic device 112 and a pad connected to an external substrate.

Thus, the first solder ball 109 is formed on at least one of the first pads 106, and the processor chip 110 is attached to the first pad 106 through the first solder ball 109.

In addition, the bonding paste 111 is formed on at least another of the first pads 106, and accordingly, the electronic device 112 is attached to the first pad 106 through the bonding paste 111.

The electronic device 112 may be a passive device. For example, the electronic device 112 may be a resistor, an inductor, or a capacitor. Preferably, the electronic device 112 may be a multiple layer ceramic capacitor (MLCC).

The bonding paste 111 may include at least one solder cream selected from the group consisting of a low-melting-point solder, a high-melting-point solder, a solder including alloy particles, a resin-containing solder, and a combination thereof, or a metallic material having an adhesive property. If necessary, the bonding paste 111 may include metallic powder to ensure electric conductivity.

As the bonding paste 111 is applied on the at least another of the first pads 106, the electronic device 112 is mounted on the applied bonding paste 111, so that the bonding paste 111 is deposited in a lateral side direction of the electronic device 112.

In addition, the second solder ball 116 is formed on the exposed surface of the second pad 107 formed on a surface of the third insulating layer 105.

As described above, according to the printed circuit board of the present invention, the electronic device 112 and the processor chip 110 are not buried in at least one of the first insulating layer 101, the second insulating layer 104, and the third insulating layer 105, but formed on the second insulating layer 104, to be exposed to the outside.

The electronic device 112 and the processor chip 110 are buried in a molding layer (to be described later) formed in a package process which will be performed later together with an upper substrate.

Meanwhile, the metal bump 115 is formed on at least one of the first pads 106.

The metal bump 115 is formed on an upper surface of the first pad 106 exposed through the protective layer 108.

In addition, the metal bump 115 protrudes from a surface of the protective layer 108. The metal bump 115 may have the shape of a post having upper and lower widths different from each other.

In this case, preferably, the metal bump 115 may be formed in at least two. For example, the metal bumps 115 may be formed on any one first pad and another first pad, which are formed at the left and right sides of the central first pad among the first pads 106, respectively.

As shown in this figure, the metal bumps 115 may be formed on the leftmost first pad, any one first pad adjacent to the leftmost first pad, the rightmost first pad, and any one first pad adjacent to the rightmost first pad, respectively.

That is, the metal bump 115 is used to constitute a package together with the upper substrate. Accordingly, at least one metal bump 115 is formed at each of the left and right sides so as to easily constitute the package together with the upper substrate.

In this case, the metal bump 115 is preferably formed higher than the electronic device 112 and the processor chip 110, which are attached onto the second insulating layer 104.

Preferably, a portion of the metal bump 115 protruding upward of the protective layer 108 has a thickness of 100 μm to 150 μm.

The metal bump 115 includes a first bump 113 contacting the first pad 106 and a second bump 114 formed on the first bump 113.

The first bump 113 is formed of a metallic material such as copper or Sn (tin) through plating. The first bump 113 includes a first part buried in the protective layer 108 and a second part protruding upward of the protective layer 108.

In this case, the first part may have the shape of a post having upper and lower widths equal to each other. The second part may also have the shape of a post having upper and lower widths equal to each other. However, the first part and the second part are formed to have different widths.

That is, the upper and lower widths of the first part are the same as the width of the opening of the protective layer 108. However, the upper and lower widths of the second part are formed greater than the width of the opening of the protective layer 108.

Accordingly, the second part is formed to extend to an upper surface of the protective layer 108.

The second bump 114 is a surface treatment layer for protecting an upper surface of the first bump 113.

The second bump 114 may be formed through any one of surface treatment processes such as organic solderability preservative, electroless gold plating (ENEPIG), and thin-nickel electroless palladium immersion gold (EPIG).

The second bump 114 may be formed of soft gold including Ni/Au. The second bump 114 may be formed with a thickness of 5 μm to 10 μm. The second bump 114 is formed on only the upper surface of the first bump 113.

FIGS. 3 to 14 are sectional views illustrating a method for manufacturing the printed circuit board shown in FIG. 2 in sequence of processes.

First, referring to FIG. 3, a first insulating layer 101, which serves as a base when the printed circuit board 100 is manufactured, is prepared.

The first insulating layer 101 is a base material used to form a circuit pattern existing in the printed circuit board 100.

The first insulating layer 101 may be a thermosetting or thermoplastic polymeric substrate, a ceramic substrate, an organic-inorganic composite material substrate, or a glass fiber impregnated substrate. If the insulating layer includes the polymeric resin, the insulating layer may include epoxy-based insulating resin. Alternatively, the insulating layer may include polyimide-based resin.

A metal layer (not shown) is formed on at least one surface of the first insulating layer 101. The metal layer (not shown) is used to form internal circuit patterns 102.

The metal layer may be formed by performing electroless plating on the first insulating layer 101. Alternately, copper clad laminate (CCL) may be used.

In this case, when the metal layer is formed through the electroless plating, roughness is provided on an upper surface of the first insulating layer 101, so that the metal layer can be smoothly plated.

The metal layer may be formed of a metallic material having conductivity, such as copper (Cu), iron (Fe), or an alloy thereof.

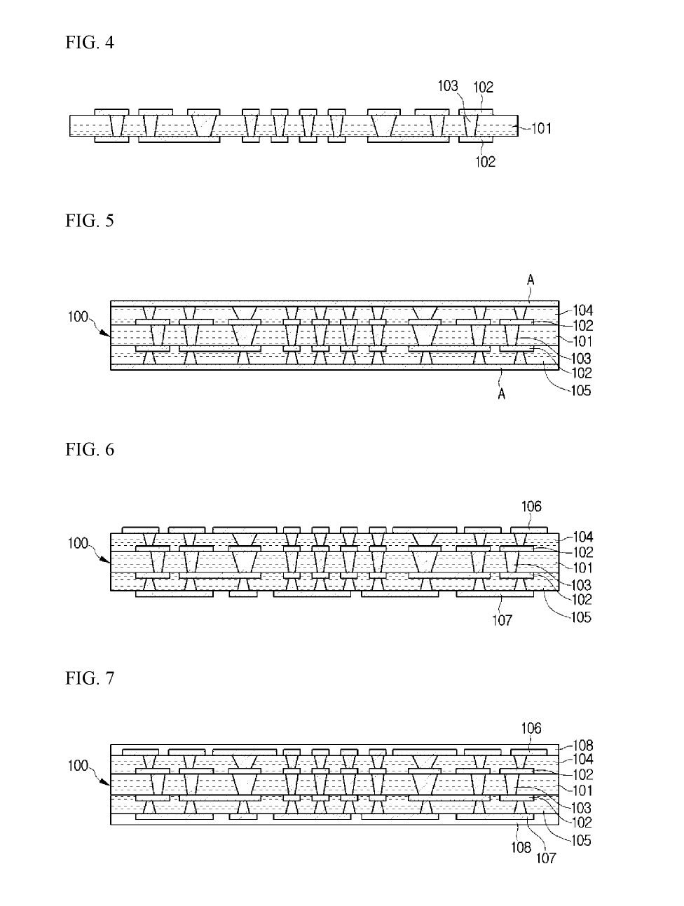

After that, referring to FIG. 4, circuit patterns 102 are formed by etching the metal layers provided on the upper and lower surfaces of the prepared first insulating layer 101. Then, a via hole (not shown) is formed in the first insulating layer 101, to form a conductive via 103 to electrically connect the circuit patterns 102 respectively formed on the upper and lower surfaces of the first insulating layer 101.

The circuit patterns 102 may be formed by coating and patterning a photoresist on upper and lower surfaces of the metal layer and performing exposure and developing processes on the photoresist to form photoresist patterns.

That is, the circuit pattern 102 may be formed through typical processes, such as an additive process, a subtractive process, a modified semi-additive process (MSAP), and a semi-additive process, of fabricating the printed circuit board, and therefore, detailed descriptions thereof will be omitted.

The conductive via 103 is formed to conduct at least one region of a first layer circuit pattern and a second layer circuit pattern. The via hole to form the conductive via 103 may be formed through a process such as a laser process, and the conductive via 103 may be formed by filling a metallic material in the formed via hole.

In this case, the metallic material constituting the conductive via 103 may be any one material selected from the group consisting of Cu, Ag, Sn, Au, Ni and Pd. The filling of the metallic material may be performed through any one of electroless plating, electrolytic plating, screen printing, sputtering, evaporation, inkjetting, and dispensing, or a combination thereof.

In this case, the sequence of forming the circuit patterns 102 and the conductive via 103 is not important. However, in order to more efficiently process the via hole, a process of forming the conductive via 103 is first performed so that the conductive via 103 is formed, and then the circuit pattern 102 is formed.

After that, referring to FIG. 5, a second insulating layer 104 is formed such that the circuit pattern 102 formed on the upper surface of the first insulating layer 101 is buried in the second insulating layer 104.

In this case, although the second insulating layer 104 may formed in one layer, the second insulating layer 104 may have a structure in which a plurality of layers are formed and laminated thereon. In addition, the second insulating layer 104 may include a plurality of layers formed of the same material including epoxy, phenolic resin, prepreg, a polyimide film, an ABF film, etc.

A metal layer A may be formed on one surface of the second insulating layer 104.

The metal layer A may be provided to form a first pad 106 or an external circuit pattern (not shown) in a subsequent process.

The metal layer A functions to allow resin to easily flow or spread when a press process is performed by using heat or pressure.

A third insulating layer 105 is formed such that the circuit pattern 102 formed on the lower surface of the first insulating layer 101 is buried in the third insulating layer 105.

In this case, although the third insulating layer 105 may be formed in one layer, the third insulating layer 104 may have a structure in which a plurality of layers are formed and laminated thereon. In addition, the third insulating layer 105 may include a plurality of layers formed of the same material including epoxy, phenolic resin, prepreg, a polyimide film, an ABF film, etc.

A metal layer A may be formed on one surface of the third insulating layer 105.

The metal layer A may be provided to form the first pad 106 or the external circuit pattern (not shown) in a subsequent process.

The metal layer A functions to allow resin to easily flow or spread when a press process is performed by using heat or pressure.

Next, referring to FIG. 6, the first pad 106 is formed by etching the metal layer formed on an upper surface of the second insulating layer 104, and a via hole (not shown) is then formed in the second insulating layer 104, thereby forming a conductive via to electrically connect, to the first pad 106, the circuit pattern 102 formed on the upper surface of the first insulating layer 101.

That is, the first pad 106 may be formed through typical processes of fabricating the printed circuit board, such as an additive process, a subtractive process, a modified semi-additive process (MSAP), and a semi-additive process (SAP), and detailed descriptions thereof will be omitted.

In addition, a second pad 107 is formed by etching the metal layer formed on a lower surface of the third insulating layer 105, and a via hole (not shown) is then formed in the third insulating layer 105, thereby forming a conductive via to electrically connect, to the second pad 107, the circuit pattern 102 formed on the lower surface of the first insulating layer 101.

Next, referring to FIG. 7, protective layers 108 are formed on the upper surface of the second insulating layer 104 and the lower surface of the third insulating layer 105, respectively.

The protective layers 108 are used to protect surfaces of the second insulating layer 104, the first pad 106, the third insulating layer 105, and the second pad 107. The protective layer 108 may include at least one layer formed using at least one of solder resist, oxide, and gold (Au).

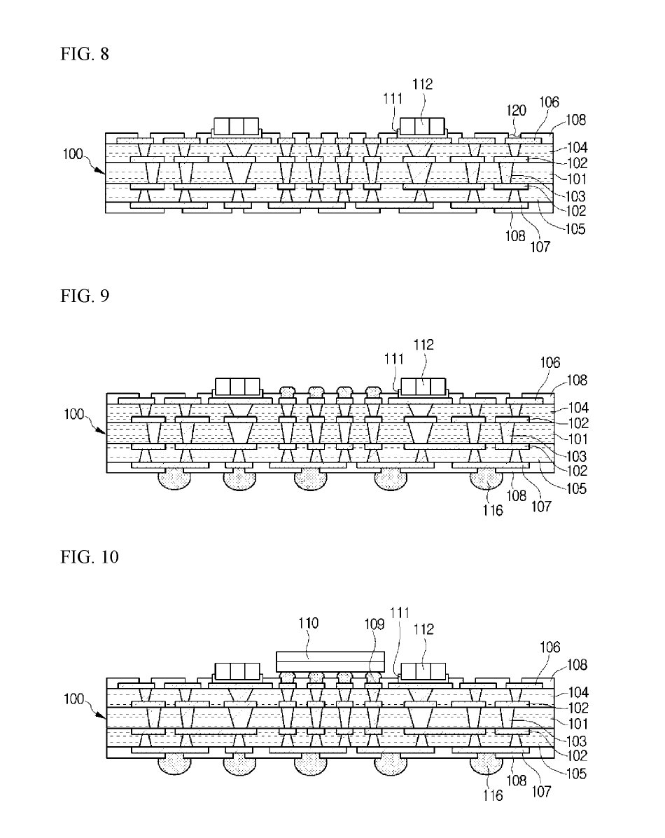

Next, referring to FIG. 8, the protective layers 108 are processed to expose the surfaces of the first pad 106 and the second pad 107 to the outside.

That is, the protective layers 108 are formed to include openings 120 to expose portions of the upper surfaces of the first and second pads 106 and 107, and the openings 120 have a smaller diameter than the first and second pads 106 and 107.

Accordingly, edges of the first and second pads 106 and 107 are protected by the protective layers 108.

After that, a bonding paste 111 is applied to at least one of the first pads exposed through the openings 120 of the protective layer 108, and an electronic device 112 is then mounted on the bonding paste 111.

The electronic device 112 may be a passive device. For example, the electronic device 112 may be a resistor, an inductor, or a capacitor. Preferably, the electronic device 112 may be a multiple layer ceramic capacitor (MLCC).

The bonding paste 111 may include at least one solder cream selected from the group consisting of a low-melting-point solder, a high-melting-point solder, a solder including alloy particles, a resin-containing solder, and a combination thereof, or a metallic material having an adhesive property. If necessary, the bonding paste 111 may include metallic powder to ensure electric conductivity.

As the bonding paste 111 is applied on at least another of the first pads 106, the electronic device 112 is mounted on the bonding paste 111, so that the bonding paste 111 is deposited in a lateral side direction of the electronic device 112.

Next, referring to FIG. 9, a first solder ball 109 is formed on at least one of the first pads 106 exposed through the openings 120 of the protective layer 108, and a second solder ball 116 is formed on at least one of the second pads 107.

Next, referring to FIG. 10, a processor chip 110 is attached onto the formed first solder ball 109.

The processor chip 110 is electrically connected to the first pad 106 by the first solder ball 109.

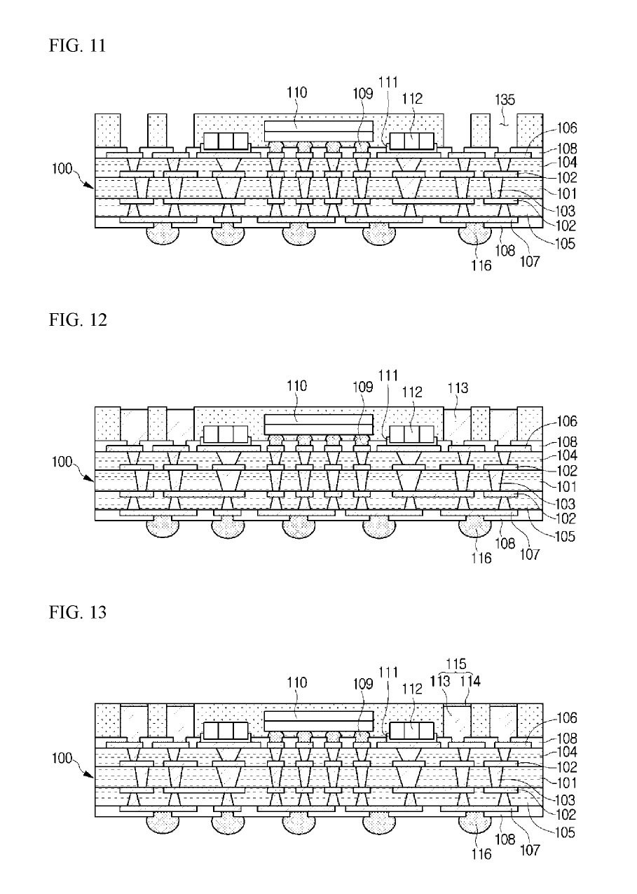

Next, referring to FIG. 11, a mask 130 is formed on the protective layer 180. Here, the mask 130 has a window to open a portion of the upper surface of the first pad 106.

In this case, before the mask 130 is formed, a plating seed layer (not shown) may be formed on upper and side surfaces of the protective layer 108 and the upper surfaces of the first pads 106 exposed through the openings 120 of the protective layer 108. The plating seed layer may preferably have a thickness of 1 μm.

The plating seed layer may be formed through an electroless plating scheme.

The electroless plating scheme may be performed in the sequence of a degreasing process, a soft etching process, a pre-catalyst process, a catalyst treatment process, an accelerator process, an electroless plating process, and an anti-oxidation treatment process. In addition, the plating seed layer may be formed by sputtering metallic particles using plasma instead of the plating scheme.

In this case, a desmear process of removing smear of the surface of the protective layer 108 may be additionally performed before the plating seed layer is plated. The desmear process is performed to provide roughness to the surface of the protective layer 108, thereby improving plating performance for forming the plating seed layer.

In addition, the plating seed layer may also be formed on the upper surface of the first pad 106 in addition to the upper and side surfaces of the protective layer 108.

Then, the mask 130 having the window 135 to open the entire region of the protective layer 108 is formed on the formed plating seed layer.

In this case, the window 135 may be formed to have a larger diameter than the opening 120. Accordingly, in addition to the upper surface of the first pad 106, the upper surface of the protective layer 108 is also exposed through the window 135.

The mask 130 may preferably include a dry film having strong thermal resistance.

Subsequently, as shown in FIG. 12, a first bump 113 is formed to be buried in the openings 120 of the protective layer 108 and portions of the mask 130.

The first bump 113 is formed by performing electrolytic plating on an alloy including a conductive material, e.g., copper using the plating seed layer, to be buried in the entire region of the opening 120 and a partial region of the window 135.

The first bumps 113 may be formed on the leftmost first pad, any one first pad adjacent to the leftmost first pad, the rightmost first pad, and any one first pad adjacent to the rightmost first pad among the plurality of first pads 106, respectively.

That is, the first bump 113 is used to constitute a package together with an upper substrate. Accordingly, at least one first bump 113 is formed at each of the left and right sides so as to efficiently support both end portions of the upper substrate.

In this case, the first bump 113 is preferably formed higher than the electronic device 112 and the processor chip 110, which are attached onto the second insulating layer 104.

Preferably, a portion of the first bump 113 protruding upward of the protective layer 108 has a thickness of 100 μm to 150 μm. In this case, the thickness includes the thickness of a second bump 114 which will be formed later. Accordingly, the thickness of the first bump 113 is determined by considering the thickness of the second bump 114, and the first bump 113 is formed according to the determined thickness.

The first bump 113 is formed of a metallic material such as copper or Sn (tin) through plating. The first bump 113 includes a first part buried in the protective layer 108 and a second part protruding upward of the protective layer 108.

In this case, the first part may have the shape of a post having upper and lower widths equal to each other. The second part may also have the shape of a post having upper and lower widths equal to each other. However, the first part and the second part are formed to have different widths.

That is, the upper and lower widths of the first part are the same as the width of the opening of the protective layer 108. However, the upper and lower widths of the second part are formed greater than the width of the opening of the protective layer 108.

Accordingly, the second part is formed to extend to an upper surface of the protective layer 108.

Next, referring to FIG. 13, the second bump 114 is formed on the first bump 113.

The second bump 114 is a surface treatment layer for protecting an upper surface of the first bump 113.

The second bump 114 may be formed through any one of surface treatment processes such as organic solderability preservative, electroless gold plating (ENEPIG), and thin-nickel electroless palladium immersion gold (EPIG).

The second bump 114 may be formed of soft gold including Ni/Au. The second bump 114 may be formed with a thickness of 5 μm to 10 μm. The second bump 114 is formed on only the upper surface of the first bump 113.

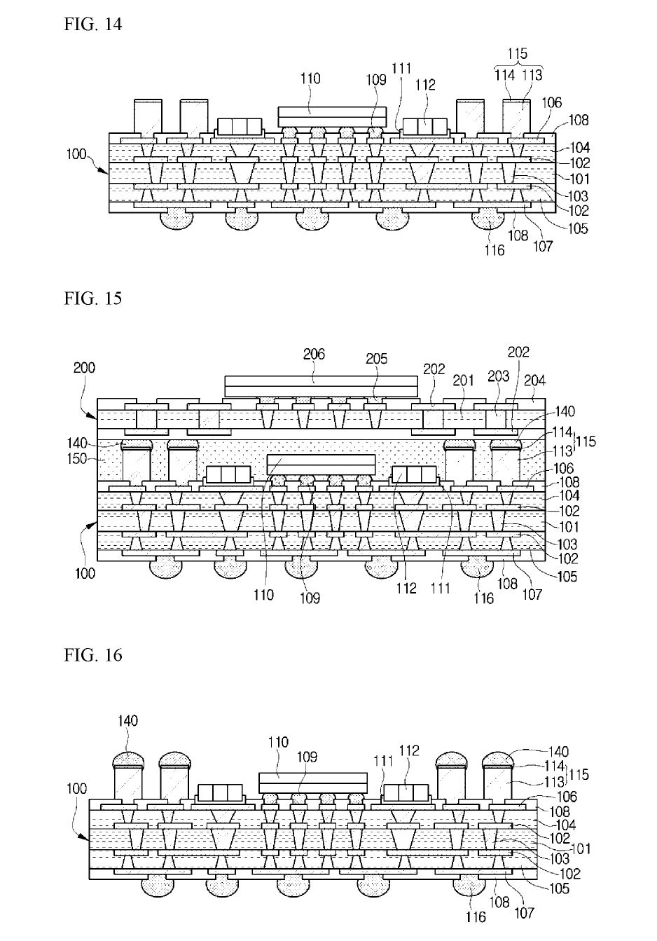

Next, referring to FIG. 14, if a metal bump 115 including the first bump 113 and the second bump 114 is formed, the mask 130 is removed.

Accordingly, the metal bump 115 is formed to protrude with a predetermined height at both ends of an upper portion of the completed printed circuit board 100.

In addition, the electronic device 112 and the processor chip 110 are disposed between the metal bumps 115 formed at both the ends.

FIG. 15 is a sectional view illustrating a package substrate according to an embodiment of the present invention.

Referring to FIG. 15, the package substrate includes a lower substrate 100 and an upper substrate 200.

The lower substrate 100 has been described above with reference to FIG. 2, and detailed description thereof will be omitted.

The upper substrate 200 includes a fourth insulating layer 201, a circuit pattern or pad 202, a conductive via 203, a protective layer 204, a solder ball 205, and a memory chip 206.

Although the fourth insulating layer 201 may be a support substrate of a printed circuit board in which a single circuit pattern is formed, the fourth insulating layer 201 may refer to an insulating layer region in which any one circuit pattern is formed in a printed circuit board substrate having a plurality of lamination structures.

The fourth insulating layer 201 forms an insulating plate, and may be a thermosetting or thermoplastic polymeric substrate, a ceramic substrate, an organic-inorganic composite material substrate, or a glass fiber impregnated substrate. When the insulating layers include polymeric resin, the insulating layers may include epoxy-based insulating resin, such as FR-4, bismaleimide triazine (BT), or ajinomoto build up film (ABF). Alternatively, the fourth insulating layer 201 may include polyimide-based resin, but the present invention is not particularly limited thereto.

The circuit pattern or pad 202 is formed on at least one surface of the fourth insulating layer 201.

The circuit pattern or pad 202 may be formed through typical processes of fabricating the printed circuit board, such as an additive process, a subtractive process, a modified semi-additive process (MSAP), and a semi-additive process (SAP), and detailed descriptions thereof will be omitted.

The conductive via 203 is formed in the fourth insulating layer 201.

The conductive via 203 electrically connects the circuit pattern or pad 202 formed on an upper surface of the fourth insulating layer 201 to the circuit pattern or pad 202 formed on a lower surface of the fourth insulating layer 201.

In this case, the conductive via 203 may be any one material selected from the group consisting of Cu, Ag, Sn, Au, Ni and Pd. The filling of the metallic material may be performed through any one of electroless plating, electrolytic plating, screen printing, sputtering, evaporation, inkjetting, and dispensing, or a combination thereof.

The solder ball 205 is formed on at least one of the circuit pattern or pads 202 formed on the upper surface of the fourth insulating layer 201.

In addition, the memory chip 206 is mounted on the formed solder ball 205.

The formation of the solder ball 205 and the mounting of the memory chip 206 are generally known in the art, and therefore, detailed descriptions thereof will be omitted in this embodiment.

The upper substrate 200 and the lower substrate 100 are coupled to each other by a connection solder ball 140.

That is, the connection solder ball 140 is formed on a metal bump 115 of the lower substrate 100.

In this case, since metal bumps 115 are formed at both ends of the lower substrate 100, respectively, connection solder balls 140 are respectively formed on the metal bumps 115, which are formed at left and right regions of the lower substrates 100, when viewed in the sectional view of the lower substrate 100.

The upper substrate 200 is attached onto the connection solder ball 140 formed on the metal bump 115. In this case, the upper substrate 200 is supported by the bump 115 and accordingly attached onto the lower substrate 100 due to an adhesive property provided by the connection solder ball 140.

A molding layer 150 is formed between the lower substrate 100 and the upper substrate 200.

The molding layer 150 protects surfaces of the lower and upper substrates 100 and 200 while protecting parts formed on the lower substrate 100.

That is, an electronic device 112 and a processor chip 110 are attached onto the lower substrate 100. In this case, in order to enhance the manufacturability of the lower substrate 100 while improving the degree of freedom in design, the electronic device 112 and the processor chip 110 are formed on an upper portion of the lower substrate 100 in a state that the electronic device 112 and the processor chip 110 are exposed to the outside.

In addition, the upper substrate 200 is attached onto the lower substrate 100. The upper substrate 200 is mounted on the metal bump 115 formed on the lower substrate 100.

In this case, since the metal bump 115 is formed higher than the electronic device 112 and the processor chip 110, the electronic device 112 and the processor chip 110 are exposed to the outside in the state that the upper substrate 200 is attached onto the lower substrate 100.

Accordingly, the molding layer 150 is formed between the lower and upper substrates 100 and 200, so that the molding layer 150 is filled in a space between the lower and upper substrates 100 and 200 formed by the metal bump 115.

The molding layer 150 may be formed of resin.

Accordingly, the lower surface of the upper substrate 200, a protective layer 204 formed under the upper substrate 200, the surface of the lower substrate 100, a protective layer 108 formed on the lower substrate 100, the metal bump 115 formed on the lower substrate 100, and the electronic device 112 and the processor chip 110, which are formed on the lower substrate 100, are buried in the molding layer 150.

According to the embodiment of the present invention, a metal post is formed on the lower substrate, and the upper substrate is attached onto the lower substrate using the metal post, thereby producing the package substrate, so that a fine pith can be formed. Accordingly, the productivity of a manufacturer can be maximized.

In addition, according to the embodiment of the present invention, the electronic device exposed to the outside is attached on the lower substrate, and the attachment space of the electronic device is molded using resin in the package process performed together with the upper substrate. Accordingly, the degree of freedom can be enhanced in the design of the substrate for the attachment of the electronic device, and the productivity can be improved in terms of product yield.

In addition, according to the embodiment of the present invention, since a molding region formed between the lower substrate and the upper substrate is supported by the metal post formed on the lower substrate, the electronic device buried in the molding region can be efficiently protected, so that the reliability of the package substrate can be improved.

FIGS. 16 to 18 are sectional views illustrating a production method for the package substrate shown in FIG. 15 in sequence of processes.

Referring to FIG. 16, a lower substrate 100 as already described above is first manufactured.

If the lower substrate 100 is manufactured, a connection solder ball 140 is formed a metal bump 115 formed on the lower substrate 100.

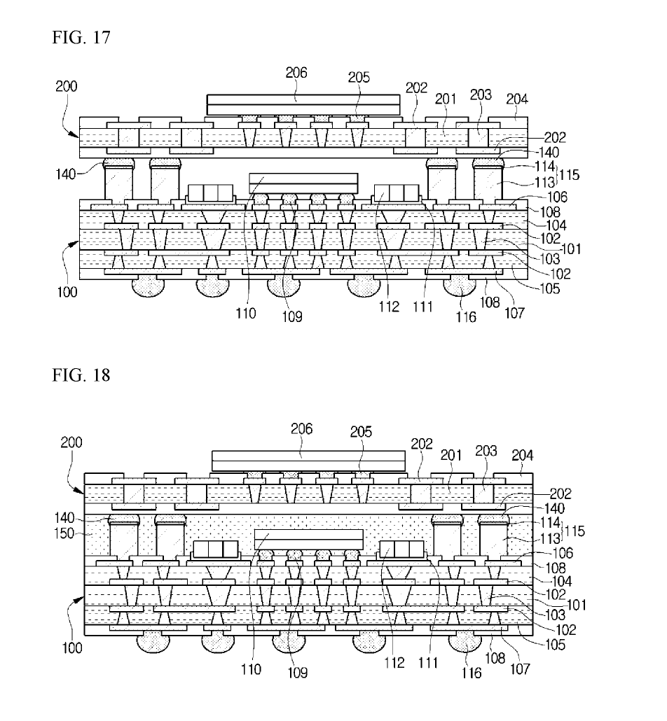

Next, referring to FIG. 17, an upper substrate 200 is mounted on the formed connection solder ball 140, and a reflow process is performed, thereby attaching the upper substrate 200 onto the lower substrate 100.

In this case, the upper substrate 200 is mounted on the lower substrate 100 in the state in which the upper substrate 200 is supported by the metal bump 115.

Next, referring to FIG. 18, resin is filled in a space between the lower and upper substrates 100 and 200, thereby forming a molding layer 150.

Accordingly, the lower surface of the upper substrate 200, a protective layer 204 formed under the upper substrate 200, the surface of the lower substrate 100, the protective layer 108 formed on the lower substrate 100, the metal bump 115 formed on the lower substrate 100, and an electronic device 112 and a processor chip 110, which are formed on the lower substrate 100, are buried in the molding layer 150.

According to the embodiment of the present invention, a metal post is formed on the lower substrate, and the upper substrate is attached onto the lower substrate using the metal post, thereby producing the package substrate, so that a fine pith can be formed. Accordingly, the productivity of a manufacturer can be maximized.

In addition, according to the embodiment of the present invention, the electronic device exposed to the outside is attached on the lower substrate, and the attachment space of the electronic device is molded using resin in the package process performed together with the upper substrate. Accordingly, the degree of freedom can be enhanced in the design of the substrate for the attachment of the electronic device, and the productivity can be improved in terms of product yield.

In addition, according to the embodiment of the present invention, since a molding region formed between the lower substrate and the upper substrate is supported by the metal post formed on the lower substrate, the electronic device buried in the molding region can be efficiently protected, so that the reliability of the package substrate can be improved.

Although the embodiments of the present invention have been described in detail, the scope of the present invention is not limited thereto, and modifications and changes made by those skilled in the art without departing from the spirit of the present invention will fall within the scope of the claims appended hereto.

1. A printed circuit board comprising:
an insulating substrate;
a plurality of pads disposed on an upper surface of the insulating substrate;
a protective layer disposed on the insulating substrate, the protective layer comprising an opening exposing upper surfaces of the plurality of pads therethrough;
a first bump disposed on a first pad and a second pad among the plurality of pads, the first bump protruding upward of a surface of the protective layer;
a second bump disposed on the first bump;
a solder ball disposed on the second bump; and
an electronic device attached onto at least one third pad among the plurality of pads by a bonding ball disposed on the third pad.

2. The printed circuit board according to claim 1, wherein the third pad is located between the first pad and the second pad among the plurality of pads disposed on the upper surface of the insulating substrate.

3. The printed circuit board according to claim 1, wherein the first bump is formed of a metallic material comprising at least one of copper or Sn (tin).

4. The printed circuit board according to claim 1, wherein the first bump comprises:
a first part buried in the protective layer;
a second part protruded upward of the surface of the protective layer and extended on the surface of the protective layer,
wherein upper and lower widths of the first bump are narrower than upper and lower widths of the second bump.

5. The printed circuit board according to claim 4, wherein the first second bump has the upper and lower widths equal to each other, and
wherein the second bump has the upper and lower widths equal to each other.

6. The printed circuit board according to claim 1, wherein an upper surface of the first bump is higher than that of the electronic device attached to the upper portion of the insulating substrate.

7. The printed circuit board according to claim 1, wherein the second bump is formed of a metallic material including gold (Au).

8. A package substrate comprising:
a lower substrate to which at least one electrode device or first chip is attached;
an upper substrate to which at least one second chip is attached, the upper substrate being coupled to the lower substrate; and
a molding layer disposed between the lower substrate and the upper substrate, the molding layer allowing the electronic device or first chip of the lower substrate, and the bumps to be buried therein,
wherein the lower substrate comprises:
an insulating substrate; and
a plurality of bumps protruding upward of a surface of the insulating substrate on the insulating substrate, the plurality of bumps having upper surfaces on which a solder ball is formed,
wherein the upper substrate is supported by the bumps, to be attached onto the lower substrate through the solder ball, and
wherein the solder ball is buried in the molding layer.

9. The package substrate according to claim 8, wherein the electronic device or first chip of the lower substrate is formed in a region between the plurality of bumps at an upper portion of the insulating substrate to be exposed to the outside.

10. The package substrate according to claim 9, wherein an upper surface of at least one of the plurality of bumps is located higher than an upper surface of the electronic device or first chip of the lower substrate.

11. The package substrate according to claim 8, wherein a plurality of pads connected to the plurality of bumps and a protective layer having an opening expositing upper surfaces of the plurality of pads are disposed on the insulating substrate, and
wherein the bump comprises:
a first bump disposed on the plurality of pads and protruded upward of a surface of the protective layer; and
a second bump disposed on the first bump.

12. The package substrate according to claim 11, wherein the first bump comprises:
a first part buried in the protective layer; and
a second part protruded upward of the surface of the protective layer and extended on the surface of the protective layer,
wherein upper and lower widths of the first bump are narrower than upper and lower widths of the second bump.

13. The package substrate according to claim 11, wherein the first bump has the upper and lower widths equal to each other, and
wherein the second bump has the upper and lower widths equal to each other.

14. The package substrate according to claim 9, wherein the second bump is formed of a metallic material including gold (Au).

15. A method for producing a package substrate, the method comprising:
manufacturing a lower substrate by preparing an insulating substrate having an upper surface on which a plurality of pads are formed, forming a protective layer having an opening exposing upper surfaces of the plurality of pads therethrough, and forming, on the plurality of pads, a plurality of bumps protruding upward of a surface of the protective layer;
manufacturing an upper substrate to which at least one chip is attached;
forming a solder ball on the bump of the lower substrate;
disposing the upper substrate on the bonding ball, thereby attaching the upper substrate supported by the plurality of bumps onto the lower substrate; and
forming a molding layer in a region between the lower substrate and the upper substrate, thereby allowing the plurality of bumps and the electronic device or first chip to be buried in the molding layer,
wherein the solder ball is buried in the molding layer.

16. The method according to claim 15, wherein the manufacturing of the lower substrate further comprises attaching an electronic device or a first chip onto at least one pad formed in a region between the plurality of bumps,
wherein the electronic device or first chip is formed at an upper portion of the lower substrate to be exposed to the outside.

17. The method according to claim 16, wherein the electronic device or first chip has a height lower than that of the plurality of bumps.

18. The method according to claim 15, wherein the bump comprises:
a first bump disposed on the plurality of pads and protruded upward of a surface of the protective layer; and
a second bump disposed on the first bump.

19. The method according to claim 18, wherein the first bump comprises:
a first part buried in the protective layer; and
a second part protruded upward of the surface of the protective layer and extended on the surface of the protective layer.

20. The method according to claim 19, wherein the first second bump has the upper and lower widths equal to each other, and
wherein the second bump has the upper and lower widths equal to each other.
